(19) United States
(12) Patent Application Publication
(10) Pub. No.: US 2025/0293029 A1
(43) Pub. Date: Sep. 18, 2025

(54) METHOD OF MANUFACTURING INTEGRATED CIRCUIT DEVICE USING METAL-ORGANIC FRAMEWORK

(71) Applicant: Samsung Electronics Co., Ltd., Suwon-si (KR)

(72) Inventors: Yongbeom Seo, Suwon-si (KR); Ji Young Park, Suwon-si (KR); Changmin Park, Suwon-si (KR); Heeyoung Go, Suwon-si (KR)

(73) Assignee: Samsung Electronics Co., Ltd., Suwon-si (KR)

(21) Appl. No.: 18/970,815

(22) Filed: Dec. 5, 2024

(30) Foreign Application Priority Data
Mar. 13, 2024 (KR) 10-2024-0035435

(51) Int. Cl. H01L 21/027; G03F 7/11; G03F 7/16; H01L 21/311

(52) U.S. Cl. CPC H01L 21/0275; G03F 7/11; G03F 7/165; G03F 7/167; H01L 21/31144

(57) ABSTRACT

A method of manufacturing an integrated circuit device comprises forming a device layer on a substrate. A photoresist pattern comprising a metal structure network is formed on a partial region of the device layer using a photolithography process. A metal-organic framework pattern comprising at least one organic ligand layer and at least one metal-containing layer is formed on the photoresist pattern. The device layer may be etched by using the metal-organic framework pattern and the photoresist pattern as etch masks. The formation of the metal-organic framework pattern comprises forming an organic ligand monolayer, which is selectively bonded to metal atoms exposed on the substrate, by supplying a vapor-phase organic ligand precursor onto the substrate, and forming a metal-containing monolayer, which selectively bonded to the organic ligand monolayer, by supplying a vapor-phase metal precursor onto a resultant structure from the forming of the organic ligand monolayer.

### CROSS-REFERENCE TO RELATED APPLICATIONS

This present application claims priority to and the benefit under 35 U.S.C. § 119(a)-(d) to Korean Patent Application No. 10-2024-0035435, filed on Mar. 13, 2024, in the Korean Intellectual Property Office, the disclosure of which is incorporated by reference herein in its entirety.

### BACKGROUND

The inventive concept relates to a method of manufacturing an integrated circuit (IC) device, and more particularly, to a method of manufacturing an IC device using a metal-organic framework.

As the downscaling of IC devices has rapidly progressed, the IC devices may have not only relatively high operation speed but also operation accuracy. Accordingly, various studies are being carried out to provide IC devices having structures capable of providing optimum performance and improving reliability.

### SUMMARY

The inventive concept provides a method of manufacturing an integrated circuit (IC) device, which has a device region with a reduced area due to the downscaling of IC devices and may improve the reliability of the IC devices even when pitches of components included in the device region are reduced.

According to an aspect of the present disclosure, a method of manufacturing an IC device is provided. The method includes forming a device layer on a substrate. A photoresist pattern including a metal structure network is formed on a partial region of the device layer by using a photolithography process. A metal-organic framework pattern including at least one organic ligand layer and at least one metal-containing layer is formed on the photoresist pattern. The device layer may be etched by using the metal-organic framework pattern and the photoresist pattern as etch masks. The formation of the metal-organic framework pattern includes forming an organic ligand monolayer by supplying a vapor-phase organic ligand precursor onto the substrate, the organic ligand monolayer being selectively bonded to a metal atom exposed on the substrate, and forming a metal-containing monolayer by supplying a vapor-phase metal precursor onto a resultant structure from the forming of the organic ligand monolayer, the metal-containing monolayer being selectively bonded to the organic ligand monolayer.

According to another aspect of the present disclosure, a method of manufacturing an IC device is provided. The method includes forming a device layer on a substrate. A resist lower film is formed on the device layer. A photoresist pattern including a metal structure network is formed on a partial region of the resist lower film by using a photolithography process such that the photoresist pattern has a first thickness in a vertical direction, wherein the vertical direction is perpendicular to a main surface of the substrate. A metal-organic framework pattern including at least one organic ligand layer and at least one metal-containing layer is formed on the photoresist pattern such that the metal-organic framework pattern has a second thickness that is greater than the first thickness in the vertical direction. The device layer is etched by using the metal-organic framework pattern and the photoresist pattern as an etch mask. The formation of the metal-organic framework pattern includes forming an organic ligand monolayer by supplying a vapor-phase organic ligand precursor onto the substrate, the organic ligand monolayer being selectively bonded to a metal atom exposed on the substrate, and forming a metal-containing monolayer by supplying a vapor-phase metal precursor onto a resultant structure from the forming of the organic ligand monolayer, the metal-containing monolayer being selectively bonded to the organic ligand monolayer. In the forming of the organic ligand monolayer, the organic ligand precursor includes a bidentate ligand. In the formation of the metal-containing monolayer, the metal precursor includes at least one metal element selected from tin (Sn), copper (Cu), aluminum (Al), titanium (Ti), tungsten (W), hafnium (Hf), antimony (Sb), indium (In), bismuth (Bi), silver (Ag), tellurium (Te), gold (Au), lead (Pb), zinc (Zn), zirconium (Zr), vanadium (V), chromium (Cr), cobalt (Co), nickel (Ni), gallium (Ga), manganese (Mn), strontium (Sr), cadmium (Cd), molybdenum (Mo), tantalum (Ta), niobium (Nb), cesium (Cs), barium (Ba), lanthanum (La), cerium (Ce), and iron (Fe).

According to another aspect of the present disclosure, a method of manufacturing an IC device is provided. The method includes forming an insulating film on a substrate. A resist lower film is formed on the insulating film. A photoresist pattern including a metal structure network is formed on a partial region of the resist lower film by using a photolithography process such that the photoresist pattern has a first thickness in a vertical direction, wherein the vertical direction is perpendicular to a main surface of the substrate. A metal-organic framework pattern including at least one organic ligand layer and at least one metal-containing layer is formed on the photoresist pattern such that the metal-organic framework has a second thickness, wherein the second thickness is greater than the first thickness in the vertical direction. Partial regions of the insulating layer are etched by using the metal-organic framework pattern and the photoresist pattern as an etch mask, and thus, a plurality of trenches are formed in the insulating layer. A plurality of conductive layers are formed to fill the plurality of trenches. The formation of the metal-organic framework pattern further includes forming an organic ligand monolayer by supplying a vapor-phase organic ligand precursor onto the substrate, the organic ligand monolayer being selectively bonded to a metal atom that is exposed on the substrate, forming a metal-containing monolayer by supplying a vapor-phase metal precursor onto a resultant structure from the forming of the organic ligand monolayer, the metal-containing monolayer being selectively bonded to the organic ligand monolayer, and alternately repeating the forming of the organic ligand monolayer and the forming of the metal-containing monolayer such that the metal-organic framework pattern having the second thickness is obtained.

### BRIEF DESCRIPTION OF THE DRAWINGS

Embodiments will be more clearly understood from the following detailed description taken in conjunction with the accompanying drawings in which:

FIG. 1 is a flowchart of a method of manufacturing an integrated circuit (IC) device, according to some embodiments;

FIGS. 2A to 2K are cross-sectional views of a process sequence, which specifically illustrate a method of manufacturing an IC device, according to some embodiments; and

FIG. 3 is a plan view of a plurality of conductive layers obtained by using a method of manufacturing an IC device, according to some embodiments.

### DETAILED DESCRIPTION OF THE EMBODIMENTS

Hereinafter, embodiments will be described in detail with reference to the accompanying drawings. The same reference numerals are used to denote the same elements in the drawings, and repeated descriptions thereof are omitted.

As used herein, an abbreviation “Me” refers to a methyl group, an abbreviation “Et” refers to an ethyl group, an abbreviation “Pr” refers to a propyl group, an abbreviation “iPr” refers to an isopropyl group, an abbreviation “Bu” refers to a butyl group, an abbreviation “iBu” refers to an isobutyl group, an abbreviation “nBu” refers to a normal butyl group, an abbreviation “tBu” refers to a tert-butyl group (or a 1,1-dimethylethyl group), an abbreviation “Ph” refers to a phenyl group, an abbreviation “Cp” refers to cyclopentadienyl, “thd” refers to 2,2,6,6-tetramethyl heptanedionate, an abbreviation “Nbmyl” refers to a tert-amyl group (CH₃CH₂C(CH₃)₂—), and an abbreviation “tAmyl” refers to a tert-amyl group (CH₃CH₂C(CH₃)₂—).

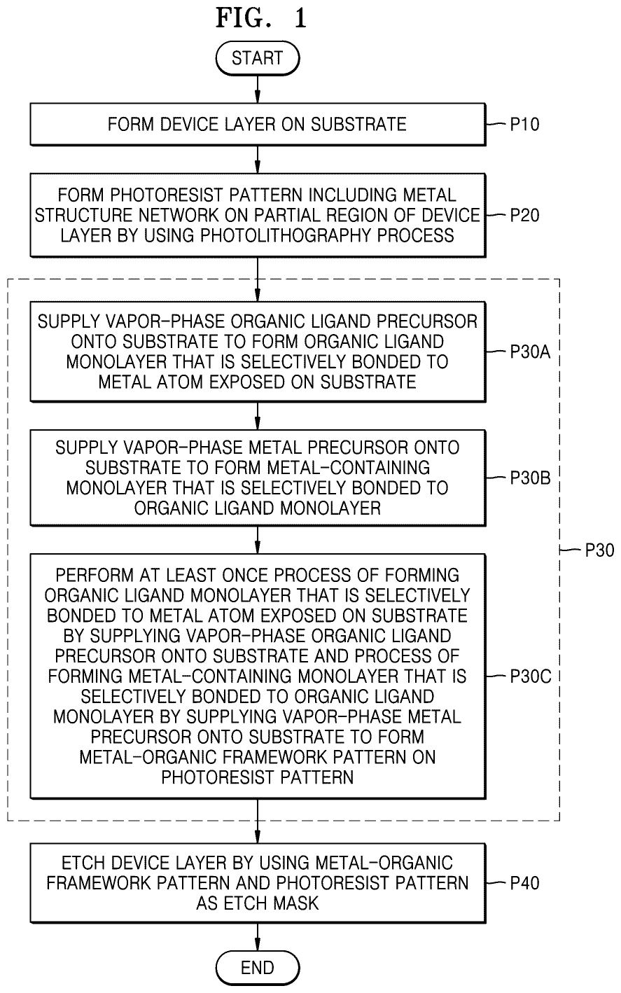

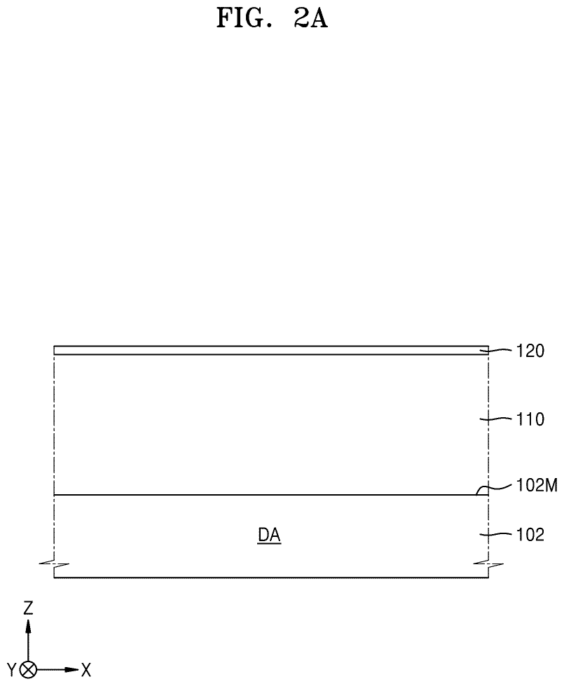

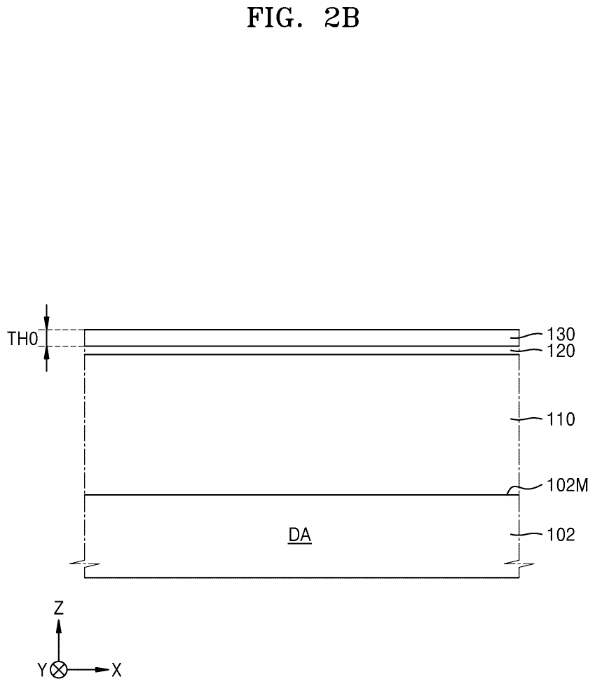

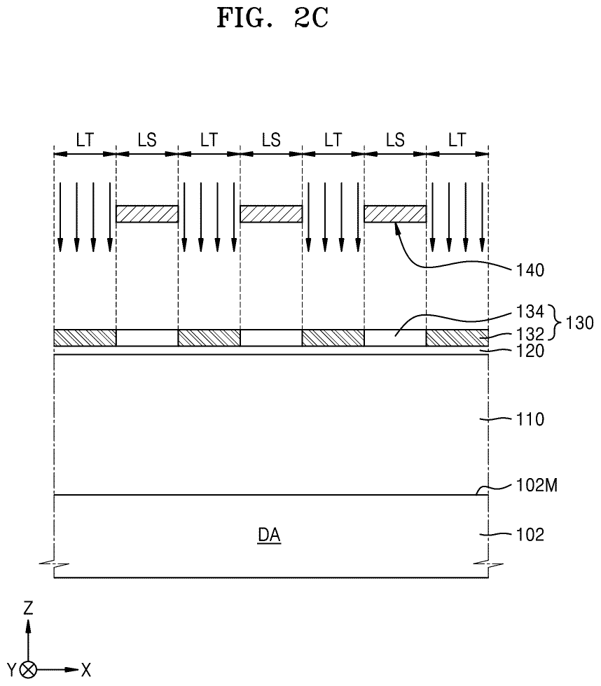

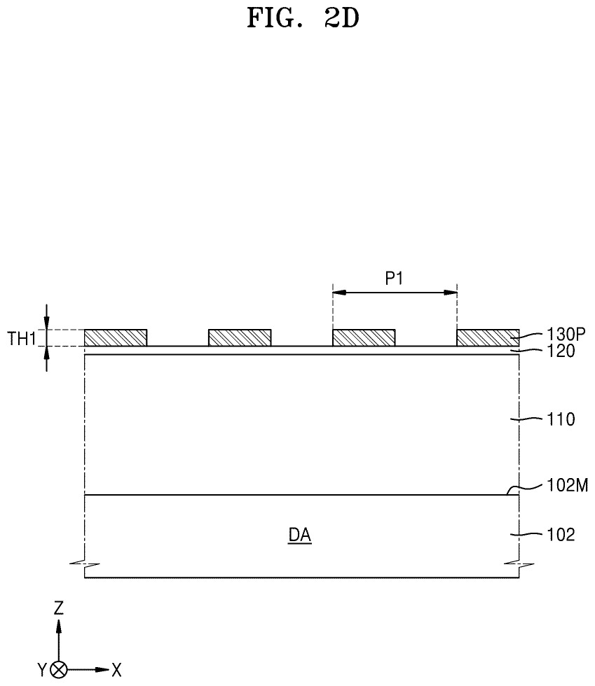

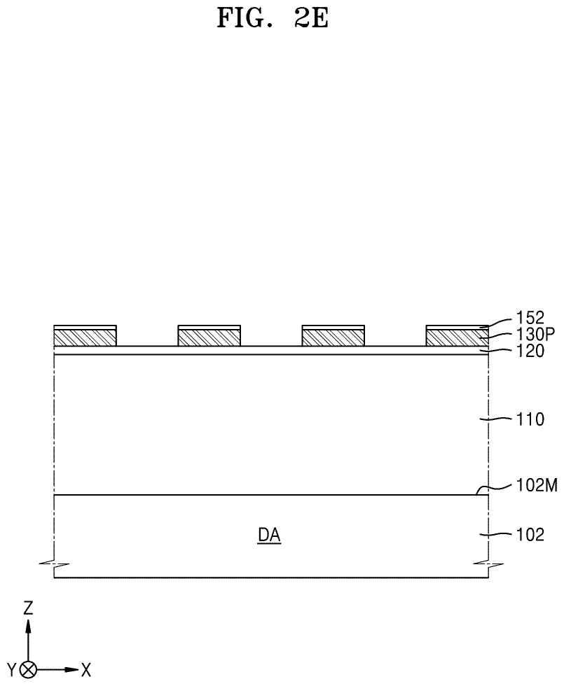

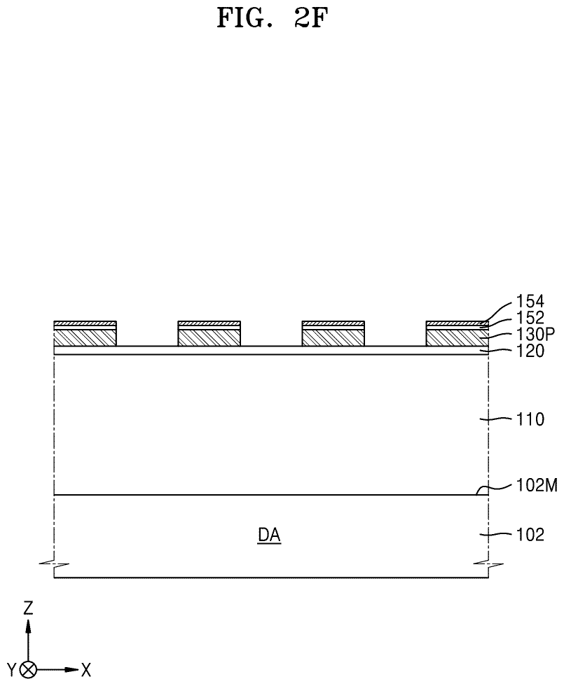

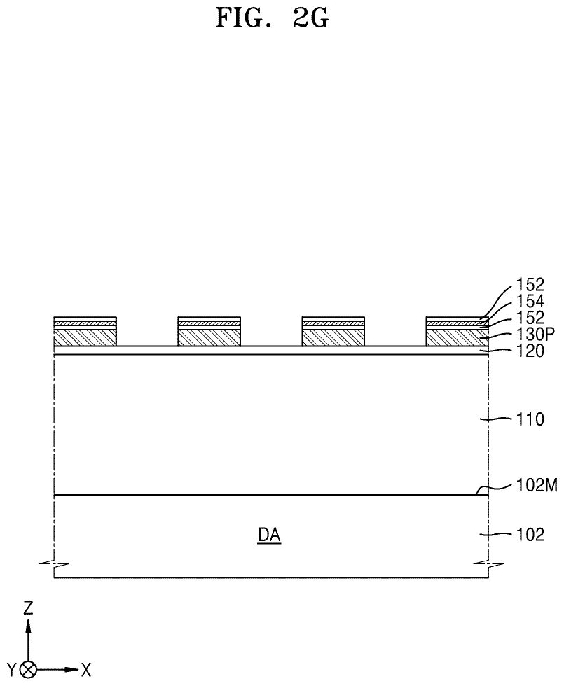

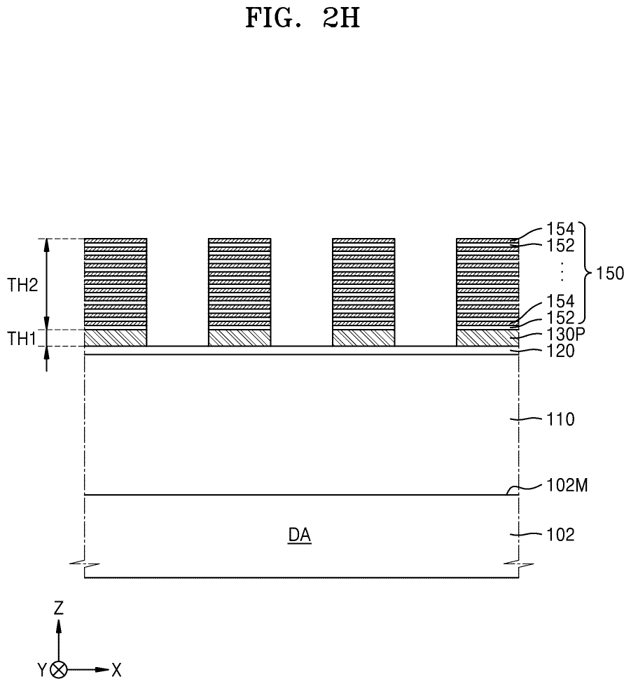

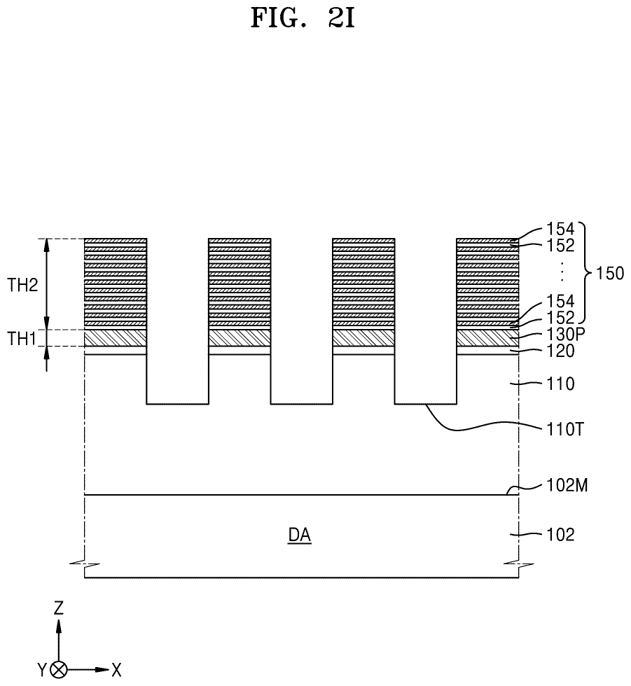

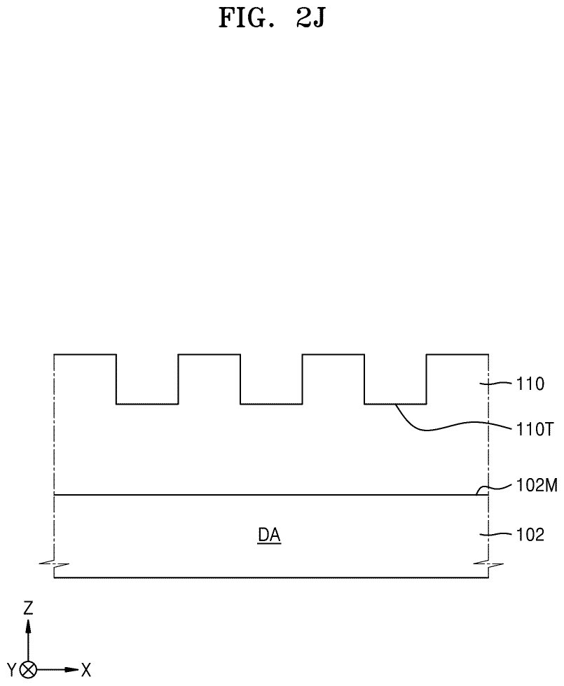

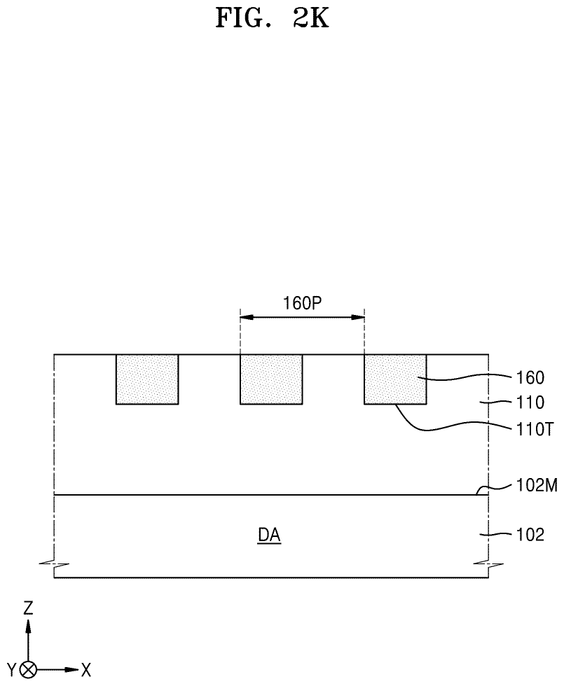

FIG. 1 is a flowchart of a method of manufacturing an integrated circuit (IC) device, according to some embodiments. FIGS. 2A to 2K are cross-sectional views of a process sequence, which specifically illustrate a method of manufacturing an IC device, according to some embodiments. Hereinafter, the method of manufacturing the IC device, according to the embodiments, is described with reference to FIGS. 1 and 2A to 2K.

Referring to FIGS. 1 and 2A, in process P10, a substrate 102 having a main surface 102M may be provided, and a device layer 110 may be formed on the main surface 102M of the substrate 102. Thereafter, a resist lower film 120 may be formed on the device layer 110.

The substrate 102 may include a semiconductor substrate. In embodiments, the semiconductor substrate may include an elemental semiconductor, such as silicon (Si) or germanium (Ge). In other embodiments, the semiconductor substrate may include a compound semiconductor, such as silicon germanium (SiGe), silicon carbide (SiC), gallium arsenide (GaAs), indium arsenide (InAs), and/or indium phosphide (InP). In still other embodiments, the semiconductor substrate may have a silicon-on-insulator (SOI) structure.

The substrate 102 may include a semiconductor die area DA. The semiconductor die area DA may be a region where a semiconductor die is to be formed or a region where a semiconductor device including a plurality of individual devices of various types is to be formed. The plurality of individual devices may include various microelectronic devices, for example, metal-oxide-semiconductor field effect transistors (MOSFETs) (e.g., complementary metal-insulator-semiconductor (CMOS) transistors), system large-scale integration (LSI), image sensors (e.g., CMOS imaging sensor (CIS)), micro-electro-mechanical system (MEMS), active devices, and/or passive devices. In some embodiments, the semiconductor die area DA may be a region for forming a memory semiconductor chip or a logic circuit chip. For example, a semiconductor die area DA may be an area for forming a volatile memory semiconductor chip, such as dynamic random access memory (DRAM) and static RAM (SRAM), and/or a non-volatile memory semiconductor chip, such as phase-change RAM (PRAM), magnetoresistive RAM (MRAM), ferroelectric RAM (FeRAM), and/or resistive RAM (RRAM).

The device layer 110 may be a film required to constitute devices to be formed in the semiconductor die area DA. In embodiments, the device layer 110 may include an insulating film or a conductive film. For example, the device layer 110 may include a metal, an alloy, a metal carbide, a metal nitride, a metal oxynitride, a metal oxycarbide, semiconductor, polysilicon, oxide, nitride, oxynitride, or a combination thereof, without being limited thereto. The present embodiment pertains to an example in which the device layer 110 includes the insulating film.

The resist lower film 120 may be between the device layer 110 and a photoresist film (refer to 130 in FIG. 2B) formed in a subsequent process and prevent the occurrence of problems caused when radiation reflected from under the photoresist film 130 is scattered into the photoresist film 130. In some embodiments, the resist lower film 120 may include a carbon-containing film. For example, the resist lower film 120 may include a carbon film, a doped carbon film, and/or an amorphous carbon layer (ACL). The doped carbon film may include a dopant including oxygen (O), silicon (Si), nitrogen (N), tungsten (W), boron (B), iodine (I), chlorine (Cl), or a combination thereof. The resist lower film 120 may have a thickness of about 1 nm to about 25 nm. The resist lower film 120 may be formed by using a plasma-enhanced chemical vapor deposition (PECVD) process or an atomic layer deposition (ALD) process, without being limited thereto.

In process P20 of FIG. 1, a photoresist pattern (refer to 130P in FIG. 2D) covering the resist lower film 120 may be formed on a partial region of the device layer 110 by using a photolithography process. The photoresist pattern 130P may include a network (hereinafter, referred to as a “metal structure network”) including a crosslinked structure (e.g., an M-O-M crosslinked structure) including a plurality of metal atoms M and a plurality of oxygen atoms O. The photoresist pattern (refer to 130P in FIG. 2D) may be formed to a thickness TH1, which is greater than about 5 Å and less than about 100 Å in a vertical direction (Z direction) perpendicular to the main surface 102M of the substrate 102. The photoresist pattern (refer to 130P in FIG. 2D) may be formed by using a dry process or a wet process.

Examples of processes of forming the photoresist pattern (refer to 130P in FIG. 2D) are described in further detail with reference to FIGS. 2B to 2D.

Referring to FIG. 2B, a photoresist film 130 may be formed on the resist lower film 120 by using a dry deposition process or a coating process. The photoresist film 130 may have a thickness TH0 that is greater than about 5 Å and less than about 100 Å, in the vertical direction (Z direction) perpendicular to the main surface 102M of the substrate 102.

In some embodiments, the photoresist film 130 may be formed by using a dry deposition process incorporating a CVD process, a PECVD process, an ALD process, a plasma-enhanced ALD (PEALD) process, and/or a sputtering deposition process. In other embodiments, the photoresist film 130 may be formed by using a spin coating process, a spray coating process, and/or a dip coating process.

The photoresist film 130 may include metal-containing extreme ultraviolet radiation (EUV) resist. In some embodiments, the formation of the photoresist film 130 by using a dry deposition process may include forming a metal oxide layer by simultaneously or alternately supplying an organometallic precursor and an oxidizing material (e.g. H₂O) in vapor form onto the resist lower film 120.

The organometallic precursor may be selected from various organic metal materials. In some embodiments, the organometallic precursor may include a metal core including at least one metal atom and at least one organic ligand surrounding the metal core. In the organometallic precursor, an ionic bond, a covalent bond, a metal bond, and/or a van der Waals bond may be present between the metal core and the organic ligand.

In the organometallic precursor, the metal core may include at least one metal element, which has the form of a metal atom, a metal ion, a metal compound, a metal alloy, or a combination thereof. The metal compound may include a metal oxide, a metal nitride, a metal oxynitride, a metal silicide, a metal carbide, or a combination thereof. In some embodiments, the metal core may include at least one metal element selected from tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (V), chromium (Cr), cobalt (Co), nickel (Ni), copper (Cu), gallium (Ga), and iron (Fe), but the present disclosure is not limited thereto.

In the organometallic precursor, the organic ligand may include C1-C30 linear alkyl, C1-C30 branched alkyl, C3-C30 cycloalkyl, C2-C30 alkenyl, C2-C30 alkynyl, C6-C30 aryl, C3-C30 allyl, C1-C30 alkoxy, C6-C30 aryloxy, or a combination thereof. The organic ligand may include a hydrocarbyl group, which is substituted with at least one hetero atom functional group including an oxygen atom, a nitrogen atom, a halogen element, cyano, thio, silyl, ether, carbonyl, ester, nitro, amino, or a combination thereof. The halogen element may be fluorine (F), chlorine (Cl), bromine (Br), or iodine (I). For example, the organic ligand may include methyl, ethyl, propyl, butyl, isopropyl, tert-butyl, tert-amyl, sec-butyl, cyclopropyl, cyclobutyl, cyclopentyl, and/or cyclohexyl. In the organometallic precursor, the organometallic precursor may include a plurality of organic ligands, two of which may form one cyclic alkyl moiety. The cyclic alkyl moiety may include 1-adamantyl or 2-adamantyl.

In embodiments, when the organometallic precursor includes tin (Sn), the organometallic precursor may include (tBu)Sn(NEt₂)₂(OtBu), (tBu)Sn(NEt₂)(NH₂)(OtBu), (tBu)Sn(NEt₂)(OtBu)₂, (Me)Sn(NEt₂)(OtBu)₂, (Me)Sn(NEt₂)₂(OtBu), (tBu)Sn(NEt₂)(OtBu), (Me)₂Sn(NEt₂)(OtBu), (Me)(tBu)Sn(NEt₂)₂, (Me)(tBu)Sn(NEt₂)(OtBu), (iPr)(tBu)Sn(NMe₂)(OtBu), or a combination thereof, without being limited thereto. The organometallic precursor may be obtained by purchasing commercially available products or by synthesizing well-known precursors by using methods known to those skilled in the art.

Referring to FIG. 2C, a partial region of the photoresist film 130 may be exposed. After the photoresist film 130 is exposed, the photoresist film 130 may include an exposed area 132 and a non-exposed area 134.

As described above with reference to FIG. 2B, the photoresist film 130 may have a relatively small thickness TH0, which is in a small range of greater than about 5 Å and less than about 100 Å, in the vertical direction (Z direction) perpendicular to the main surface 102M of the substrate 102, and thus, a dose required for exposure may be significantly reduced during a process of exposing the photoresist film 130. Accordingly, the productivity of a process of manufacturing the IC device may be increased.

In some embodiments, to expose a partial region of the photoresist film 130, a photomask 140 having a plurality of light-shielding areas LS and a plurality of light-transmitting areas LT may be arranged at a predetermined position on the photoresist film 130, and the partial region of the photoresist film 130 may be exposed through the plurality of light-transmitting areas LT of the photomask 140. The partial region of the photoresist film 130 may be exposed using an EUV laser (13.5 nm), a KrF excimer laser (248 nm), an ArF excimer laser (193 nm), and/or a fluorine (F₂) excimer laser (157 nm).

In some embodiments, to expose the partial region of the photoresist film 130, the photoresist film 130 may be exposed to EUV light (13.5 nm) in a vacuum atmosphere. Physical or chemical properties may change in a portion of the photoresist film 130, which is exposed to EUV light (13.5 nm).

When the photoresist film 130 is exposed, photons in the exposed area 132 of the photoresist film 130 may be absorbed by the organometallic precursor included in the photoresist film 130, and thus, bonds between organic ligands and the metal core in the organometallic precursor may be destroyed in the exposed area 132. As a result, organometallic precursors in the exposed area 132 may be clustered into a metal oxide through condensation to form M-O-M bonds, which are formed by bonding metal atoms (M) to oxygen atoms (O). For example, a metal oxide, such as SnO₂, may be formed in the exposed area 132 of the photoresist film 130. As a result, the photoresist film 130 may have different reactivities to a vapor development atmosphere or a developer in the exposed area 132 and the non-exposed area 134.

In the organometallic precursors included in the photoresist film 130, a metal oxide film included in the exposed area 132 of the photoresist film 130 may include various materials according to a material included in the metal core. For example, the exposed area 132 of the photoresist film 130 may include a metal oxide including at least one metal element that is selected from Sn, Sb, In, Bi, Ag, Te, Au, Pb, Zn, Ti, Hf, Zr, Al, V, Cr, Co, Ni, Cu, Ga, and Fe.

Referring to FIG. 2D, in the resultant structure of FIG. 2C, a post-exposure bake (PEB) process may be performed on the photoresist film 130 including the exposed area 132, and then a dry development process may be performed to form a photoresist pattern 130P including a metal oxide.

More specifically, the photoresist film 130 may be dry developed by using organic vapor, such as organic acids. The organic acids may also include halogenated or fluorinated carboxylic acids. In embodiments, the organic acids may include trifluoroacetic acid (CF₃COOH), hexafluoro-acetylacetone (CF₃CCH₂CCF₃), trifluoroacetic acid anhydride ((CF₃CO)₂O), acetic acid anhydride((CH₃CO)₂O), trichloroacetic acid (CCl₃COOH), mono-fluoroacetic acid (CFH₂COOH), di-fluoroacetic acid (CF₂HCOOH), chloro-difluoro-acetic acid, thioacetic acid (CH₃COSH), thioglycolic acid (HSCH₂CO₂H), or a combination thereof, without being limited thereto. In some embodiments, to perform the dry development process, a mixture of carboxylic acid and hydrogen halide may be further supplied onto the photoresist film 130 in addition to organic vapor including the organic acids. In some embodiments, the organic vapor may be supplied onto the photoresist film together with an inert gas selected from helium (He), neon (Ne), argon (Ar), xenon (Xe), and nitrogen (N₂) and/or a carrier gas or supplied onto the photoresist film without the inert gas and the carrier gas. The dry development process may be performed in a plasma atmosphere or may be performed by using a thermal process in which heat is applied in a plasma-free atmosphere without plasma assistance.

The photoresist pattern 130P may include a metal oxide film. The metal oxide film may include at least one metal element that is selected from Sn, Sb, In, Bi, Ag, Te, Au, Pb, Zn, Ti, Hf, Zr, Al, V, Cr, Co, Ni, Cu, Ga, and Fe. For example, the metal oxide film included in the photoresist pattern 130P may include SnO₂.

In other embodiments, to form the photoresist pattern 130P, the photoresist film 130 including the exposed area 132 may be wet developed as illustrated in FIG. 2C. In some embodiments, the photoresist film 130F may be wet developed by using n-butyl acetate or 2-heptanone as the developer, but a kind of the developer is not limited thereto.

The photoresist pattern 130P may include a plurality of line patterns, which are arranged at a pitch P1 greater than about 5 nm and less than about 28 nm in a first direction (X direction) parallel to the main surface 102M of the substrate 102 and are apart from each other in the first direction (X direction).

Referring back to FIG. 1, in process P30, a metal-organic framework pattern (refer to 150 in FIG. 2H) including at least one organic ligand layer and at least one metal-containing layer may be formed on the photoresist pattern 130P.

As shown in FIG. 2H, the metal-organic framework pattern 150 may be formed to have a thickness TH2 in the vertical direction (Z direction), which is perpendicular to the main surface 102M of the substrate 102. The thickness TH2 may be greater than the thickness TH1 of the photoresist pattern 130P. However, according to the inventive concept, the thickness TH2 of the metal-organic framework pattern 150 is not limited to that illustrated in FIG. 2H and may be variously determined as needed.

Examples of processes of forming the metal-organic framework pattern (refer to 150 in FIG. 2H) according to process P30 of FIG. 1 are described with reference to FIGS. 1 and 2E to 2H.

Referring to FIGS. 1 and 2E, in process P30A, a vapor-phase organic ligand precursor may be supplied onto the resultant structure obtained in the process of FIG. 2D, and thus, an organic ligand monolayer 152 that is selectively bonded to a metal atom exposed on the surface of the photoresist pattern 130P may be formed. The vapor-phase organic ligand precursor may include a bidentate ligand having two reactive groups in a plasma atmosphere, and one of the two reactive groups included in the organic ligand precursor may be coordinately bonded to the metal atom exposed on the surface of the photoresist pattern 130P, and thus, the organic ligand monolayer 152 may be formed on the surface of the photoresist pattern 130P.

The organic ligand precursor used to form the organic ligand monolayer 152 may include a bidentate ligand having a structure of Formula 1:

X¹-A-X², [Formula 1]
wherein A denotes a substituted or unsubstituted C6-C60 arylene group or a substituted or unsubstituted C6-C60 heteroarylene group, and each of X¹ and X² denotes a carboxylic group, an aldehyde group, an amino group, a pyridyl group, a tetrazolyl group, a 2-(diphenylphosphino) ethyl group, a phosphoryl group, or a sulfonyl group. The pyridyl group may be directly bonded to A or bonded to A in the form of a condensed ring.

As used herein, the term “substituted or unsubstituted” may refer to being substituted or unsubstituted with at least one substituent selected from the group consisting of deuterium; a halogen group; a cyano group; a nitro group; a hydroxyl group; a carbonyl group; an ester group; an imide group; an amino group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; arylphosphine group; and heteroaryl including at least one of nitrogen (N), oxygen (O), sulfur (S), fluorine (F), silicon (Si), and selenium (Se) atoms, or refers to being substituted or unsubstituted with a linkage between at least two of the substituents described above.

As used herein, the aryl group may be a monocyclic aryl group or a polycyclic aryl group. Unless defined otherwise, the aryl group may have a carbon number of 6 to 30. When the aryl group is a monocyclic aryl group, the aryl group may be a phenyl group, a biphenyl group, or a terphenyl group, without being limited thereto. When the aryl group is a polycyclic aryl group, the aryl group may include a naphthyl group, an anthryl group, a phenanthryl group, a pyrenyl group, a perylenyl group, a chrysenyl group, or a fluorenyl group, without being limited thereto. As used herein, heteroaryl may refer to C6-C60 heteroaryl including at least one of oxygen (O), nitrogen (N), silicon (Si), and sulfur (S) as a heterogeneous element. As used herein, the above description of the aryl group may be applied, except that arylene is a divalent group. As used herein, the above description of heteroaryl may be applied, except that heteroarylene is a divalent group.

In embodiments, in Formula 1, A may denote an arylene group or a hetero arylene group of a divalent derived from one selected from the group consisting of benzene, biphenyl, terphenyl, naphthalene, anthracene, tetracene, chrysene, phenanthrene, triphenylene, fluoranthene, pyrene, and perylene. In Formula 1, A may have a substituent, and the substituent may be selected from a halogen atom (e.g., a fluorine atom, a chlorine atom, a bromine atom, or an iodine atom), a hydroxyl group, cyano, nitro, amino, amidino, hydrazine, hydrazone, carboxyl, carboxyl salts, sulfonic acid, sulfonic acid salts, phosphoric acid, phosphate, C1-C20 alkyl, and C1-C20 alkoxy, without being limited thereto.

In embodiments, in Formula 1, A denotes 1,2-phenylene, 1,3-phenylene, 1,4-phenylene, 1,2-naphthylene, 1,3-naphthylene, 1,4-naphthylene, 1,5-naphthylene, 1,6-naphthylene, 1,7-naphthylene, 1,8-naphthylene, 2,3-naphthylene, 2,6-naphthylene, 2,7-naphthylene, 1,2-anthracenylene, 1,3-anthracenylene, 1,4-anthracenylene, 1,5-anthracenylene, 1,6-anthracenylene, 1,7-anthracenylene, 1,8-anthracenylene, 1,9-anthracenylene, 1,10-anthracenylene, 2,3-anthracenylene, 2,6-anthracenylene, 2,7-anthracenylene, 2,9-anthracenylene, 2,10-anthracenylene, 9,10-anthracenylene, 4,2-biphenylene, 4,3′-biphenylene, 4,4′-biphenylene, 1,2-chrycenylene, 1,3-chrycenylene, 1,4-chrycenylene, 1,5-chrycenylene, 1,6-chrycenylene, 1,7-chrycenylene, 1,8-chrycenylene, 1,9-chrycenylene, 1,10-chrycenylene, 1,11-chrycenylene, 1,12-chrycenylene, 2,3-chrycenylene, 2,4-chrycenylene, 2,5-chrycenylene, 2,6-chrycenylene, 2,8-chrycenylene, 2,9-chrycenylene, 2,10-chrycenylene, 2,11-chrycenylene, 2,12-chrycenylene, 3,4-chrycenylene, 3,5-chrycenylene, 3,6-chrycenylene, 3,9-chrycenylene, 3,10-chrycenylene, 3,11-chrycenylene, 3,12-chrycenylene, 4,5-chrycenylene, 4,6-chrycenylene, 4,11-chrycenylene, 4,12-chrycenylene, 5,6-chrycenylene, 5,11-chrycenylene, 5,12-chrycenylene, or 6,12-chrycenylene, without being limited thereto.

In other embodiments, in Formula 1, A may be selected from the following structures, without being limited thereto. In the following structures, * denotes a linking site.

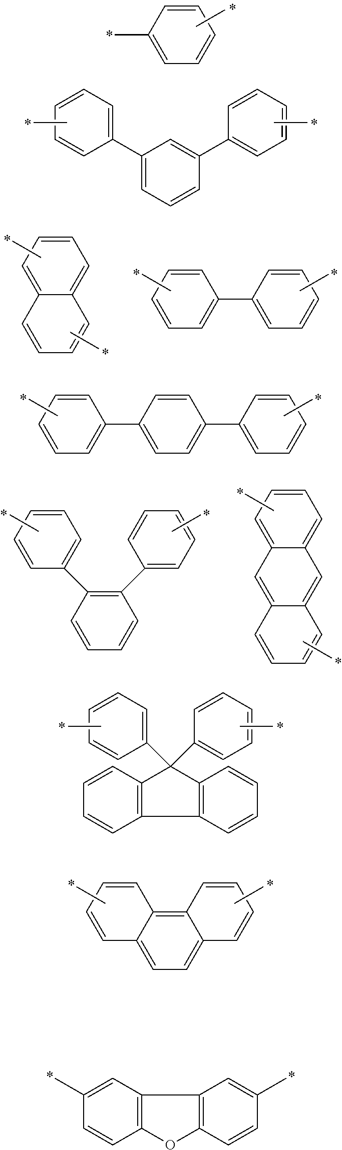

In the bidentate ligand according to Formula 1, each of X¹ and X² may be an anionic group. In the organic ligand precursor according to Formula 1, X¹ and X² may be arranged in opposite directions. For example, in the organic ligand precursor according to Formula 1, X¹ and X² may be positioned at an angle of 180 degrees to each other. In Formula 1, when A is arylene, X¹ and X² may be in a para position. For example, when A is phenylene, X¹ and X² may be respectively bonded to sites 1 and 4 of a phenylene ring. When A is biphenylene, X¹ and X² may be respectively bonded to sites 4 and 4′ in a biphenylene structure.

In some embodiments, the organic ligand precursor may be selected from the following structures, without being limited thereto:

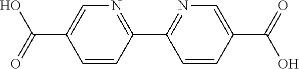 [SMILES: O=C(O)c1ccc(-c2ccc(C(=O)O)cn2)nc1]

(2,2′-bipyridine-5,5′-dicarboxylic acid)

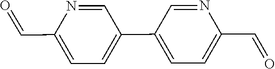 [SMILES: O=Cc1ccc(-c2ccc(C=O)nc2)cn1]

([3,3-bipyridine]-6,6-dicarboxaldehyde)

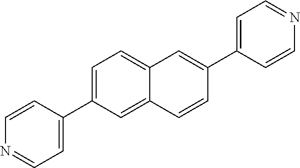 [SMILES: c1cc(-c2ccc3cc(-c4ccncc4)ccc3c2)ccn1]

(2,6-di(pyridin-4-yl)naphthalene)

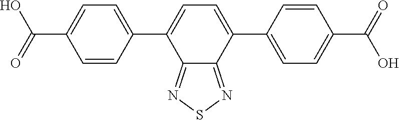 [SMILES: O=C(O)c1ccc(-c2ccc(-c3ccc(C(=O)O)cc3)c3nsnc23)cc1]

(4,4′-(benzo[c][1,2,5]thiadiazole-4,7-diyl)dibenzoic acid)

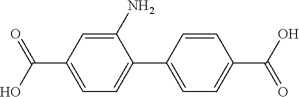 [SMILES: Nc1cc(C(=O)O)ccc1-c1ccc(C(=O)O)cc1]

(2-amino-[1,1′-biphenyl]-4,4′-dicarboxylic acid)

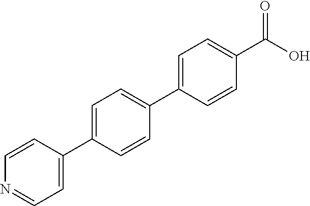 [SMILES: O=C(O)c1ccc(-c2ccc(-c3ccncc3)cc2)cc1]

(4′-(pyridin-4-yl)-[1,1′-biphenyl]-4-carboxylic acid)

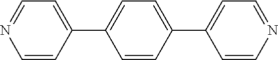 [SMILES: c1cc(-c2ccc(-c3ccncc3)cc2)ccn1]

(1,4-di(4-pyridyl)benzene)

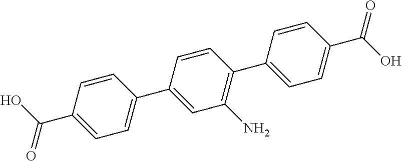 [SMILES: Nc1cc(-c2ccc(C(=O)O)cc2)ccc1-c1ccc(C(=O)O)cc1]

(2′-amino-1,1′:4,1″-terphenyl-4,4″-dicarboxylic acid)

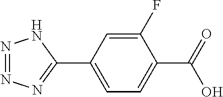 [SMILES: O=C(O)c1ccc(-c2nnn[nH]2)cc1F]

(2-fluoro-4-(1H-tetrazol-5-yl)benzoic acid)

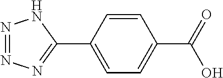 [SMILES: O=C(O)c1ccc(-c2nnn[nH]2)cc1]

(4-(1H-tetrazol-5-yl)benzoic acid)

As described with reference to FIG. 2E, the process of forming the organic ligand monolayer 152 may be performed in a vacuum atmosphere. For example, the process of forming the organic ligand monolayer 152 may be performed in a plasma atmosphere while maintaining a pressure of about 1 mTorr to about 500 mTorr, for example, about 1 mTorr to about 100 mTorr, and a temperature of about 10° C. to about 300° C., for example, about 30° C. to about 200° C. The organic ligand monolayer 152 may include a single molecular layer chelated only on the photoresist pattern 130P.

The organic ligand precursor may not react with a surface of the resist lower film 120, which is exposed around the photoresist pattern 130P. Accordingly, the organic ligand monolayer 152 may not be formed on the surface of the resist lower film 120.

The stability of structures created based on molecular modeling was analyzed in order to evaluate whether a chelator material is selectively deposited only on a surface of a metal oxide included in the photoresist pattern 130P, from among the surface of the resist lower film 120 and the surface of the metal oxide. To make the present analysis, a Vienna Ab initio Simulation Package (VASP) was used, an amorphous carbon layer (ACL) was used as the resist lower film 120, and a surface including SnO₂ cluster was used as a metal oxide included in the photoresist pattern 130P. The evaluation results show that the binding energy of terephthalic acid on a surface of the ACL was about 3.803 eV, and the binding energy of terephthalic acid on the surface including SnO₂ cluster was about −0.214 eV. From the evaluation results, it can be seen that bond between the resist lower film 120 including the ACL and terephthalic acid is relatively unstable, while bond between the photoresist pattern 130P including SnO₂ and terephthalic acid is surprisingly stable.

Accordingly, when an organic ligand precursor is supplied in a vapor phase onto a surface at which the photoresist pattern 130P and the resist lower film 120 are exposed together, an anionic reactive group derived from the organic ligand precursor in a plasma atmosphere may selectively form stable coordinate bonds only on the photoresist pattern 130P, from among the photoresist pattern 130P and the resist lower film 120. Thus, an organic ligand monolayer 152 may be selectively formed only on the photoresist pattern 130P.

Referring to FIGS. 1 and 2F, in process P30B, a vapor-phase metal precursor may be supplied onto the resultant structure of FIG. 2E in which the organic ligand monolayer 152 is formed, and thus, a metal-containing monolayer 154 that is selectively bonded to the organic ligand monolayer 152 may be formed.

The metal precursor used to form the metal-containing monolayer 154 may include at least one metal element selected from tin (Sn), copper (Cu), aluminum (Al), titanium (Ti), tungsten (W), hafnium (Hf), antimony (Sb), indium (In), bismuth (Bi), silver (Ag), tellurium (Te), gold (Au), lead (Pb), zinc (Zn), zirconium (Zr), vanadium (V), chromium (Cr), cobalt (Co), nickel (Ni), gallium (Ga), manganese (Mn), strontium (Sr), cadmium (Cd), molybdenum (Mo), tantalum (Ta), niobium (Nb), cesium (Cs), barium (Ba), lanthanum (La), cerium (Ce), and iron (Fe). In some embodiments, the metal precursor used to form the metal-containing monolayer 154 may include an organic metal compound.

In embodiments, the metal precursor used to form the metal-containing monolayer 154 may have a structure of Formula 2:

M(R¹)m(R²)n, [Formula 2]
wherein M is a metal element, R¹ denotes a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a C1-C30 alkylamino group, a C1-C30 bis(trialkylsilyl)amino group, a disubstituted phosphoric acid group), a R⁴COO— group, a R⁴SO₃— group, or a R⁴SO₂— group, wherein R⁴ denotes a substituted or unsubstituted C1-C10 alkyl group or a substituted or unsubstituted phenyl group, R² is C1-C10 alkylamine or pyridine, m is an integer of 2 to 8, and n is an integer of 0 to 6.

In Formula 2, R² may denote a hetero atom (e.g., nitrogen (N), oxygen (O), phosphorus (P), and sulfur (S)) or a neural ligand that coordinates to M through a halide.

In Formula 2, M may denote a metal element selected from Sn, Cu, Al, Ti, W, Hf, Sb, In, Bi, Ag, Te, Au, Pb, Zn, Zr, V, Cr, Co, Ni, Ga, Mn, Sr, Cd, Mo, Ta, Nb, Cs, Ba, La, Ce, and Fe.

In some embodiments, the metal precursor may include tin (Sn). In this case, the metal precursor may include tetramethyl tin (SnMe₄), tetraethyl tin (SnEt₄), trimethyl tin chloride (SnMe₃Cl), dimethyl tin dichloride (SnMe₂Cl₂), methyl tin trichloride (SnMeCl₃), tetraallyl tin, tetravinyl tin, hexaphenyl ditin (IV) (Ph₃Sn—SnPh₃), dibutyldiphenyl tin (SnBu₂Ph₂), trimethyl(phenyl) tin (SnMe₃Ph), trimethyl(phenylethynyl) tin, tricyclohexyl tin hydride, tributyl tin hydride (SnBu₃H), dibutyl tin diacetate (SnBu₂(CH₃COO)₂), tin(II) acetylacetonate (Sn(acac)₂), SnBu₃(OEt), SnBu₂(OMe)₂, SnBu₃(OMe), Sn(tBuO)₄, Sn(nBu) (tBuO)₃, tetrakis(dimethylamino)tin (Sn(NMe₂)₄), tetrakis(ethylmethylamino)tin (Sn(NMeEt)₄), tetrakis(diethylamino)tin(IV) (Sn(Me)₃(NMe₂), Sn(iPr)(NMe₂)₃, Sn(nBu)(NMe₂)₃, Sn(sBu)(NMe₂)₃, Sn(iBu)(NMe₂)₃, Sn(tBu)(NMe₂)₃, Sn(tBu)₂(NMe₂)₂, Sn(tBu)(NEt₂)₃, Sn(tbba)(tbba=N2,N3-di-tert-butyl-butane-2,3-diamide), Sn(II) (1,3-bis(1,1-dimethylethyl)-4,5-dimethyl-(4R,5R)-1,3,2-diazastannolidin-2-ylidene), bis[bis(trimethylsilyl)amino] tin (Sn[N(SiMe₃)₂]₂), or a derivative thereof, without being limited thereto.

In some embodiments, the metal precursor may include copper (Cu). In this case, the metal precursor may include Cu(hfac)₂ (hfac=1,1,1,5,5,5hexafluoro-2,4-acetylacetonate), Cu(tfac)₂(tfac=1,1,1-trifluoro-2,4-acetylacetonate), Cu₂O(CO₂)₄, Cu₃O₃(CO₂)₃), or a derivative thereof, without being limited thereto.

In some embodiments, the metal precursor may include aluminum (Al). In this case, the metal precursor may include trimethyl aluminum, triethyl aluminum, aluminum methoxide, aluminum ethoxide, or a derivative thereof, without being limited thereto.

In some embodiments, the metal precursor may include titanium (Ti). In this case, the metal precursor may include titanium tetrakis(isopropoxide)(Ti(O-iPr)₄), cyclopentadienyl titanium, titanium bis(isopropoxide)bis(2,2,6,6-tetramethyl-3,5-heptanedionate)(Ti(O-iPr)₂(thd)₂), tetrakisdimethylaminotitanium (TDMAT, Ti(NMe₂)₄), tetrakis(diethylamino)titanium (TEMAT, (Et₂N)₄Ti), trimethoxy(pentamethylcyclopentadienyl)titanium ((Cp*)Ti(OMe)₃), or a derivative thereof, without being limited thereto.

In some embodiments, the metal precursor may include tungsten (W). In this case, the metal precursor may include bis(tert-butylimido) bis(tert-butylamido)tungsten ((tBuN)₂ W(N(H)tBu)₂), bis(tert-butylimido) bis(dimethylamido)tungsten ((tBuN)₂ W(NMe₂)₂), bis(tert-butylimido) bis(diethylamido)tungsten ((tBuN)₂ W(NEt₂)₂), bis(tert-butylimido) bis(ethylmethylamido)tungsten ((tBuN)₂ W(NEtMe)₂), or a derivative thereof, without being limited thereto.

In embodiments, the metal precursor may include hafnium (Hf). In this case, the metal precursor may include Hf(iPr)(NMe₂)₃, HfCp₂Me₂, Hf(OtBu)₄, Hf(OEt)₄, Hf(NEt₂)₄, Hf(NMe₂)₄, Hf(NMeEt)₄, Hf(thd)₄ (thd=2,2,6,6-tetramethyl-3,5-heptanedionate), or a derivative thereof, without being limited thereto.

In some embodiments, the metal precursor may include antimony (Sb). In this case, the metal precursor may include Sb(OEt)₃, Sb(OnBu)₃, Sb(NMe₂)₃), or a derivative thereof, without being limited thereto.

In some embodiments, the metal precursor may include indium (In). In this case, the metal precursor may include indium acetate (In(CH₃COO)₃), or a derivative thereof, without being limited thereto.

In some embodiments, the metal precursor may include bismuth (Bi). In this case, the metal precursor may include Bi(MMP)₃{tris(1-methoxy-2-methyl-2-propxy)bismuth}, Bi(Ph)₃, or a derivative thereof, without being limited thereto.

In some embodiments, the metal precursor may include tellurium (Te). In this case, the metal precursor may include dimethyl tellurium (TeMe₂), diethyl tellurium (TeEt₂), di(n-butyl) tellurium (Te(nBu)₂), di(isopropyl) tellurium (Te(iPr)₂), di(t-butyl) tellurium (Te(tBu)₂), t-butyl tellurium hydride (Te(tBu)(H)), Te(OEt)₄, bis(trimethylsilyl)tellurium (Te(SiMe₃)₂), bis(triethylsilyl) tellurium (Te(SiEt₃)₂), or a derivative thereof, without being limited thereto.

In some embodiments, the metal precursor may vanadium (V). In this case, the metal precursor may include tetrakisdimethylamino vanadium(TDMAV, V(N(CH₃)₂)₄), tetrakisdiethylamino vanadium(TDEAV, V(NEt₂)₄), tetrakis(methylethylamido)vanadium(TMEAV, V(NMeEt)₄), bis(cyclopentadienyl)vanadium(Cp₂V), bis(cyclopentadienyl)dichloro vanadium(Cp₂VCl₂), or a derivative thereof, without being limited thereto.

In some embodiments, the metal precursor may include cobalt (Co). In this case, the metal precursor may be selected from β-diketonates of cobalt (II) and cobalt (III) or a derivative thereof, without being limited thereto.

In some embodiments, the metal precursor may include nickel (Ni). In this case, the metal precursor may include Ni(MeCp)₂, Ni(EtCp)₂, Ni(iPrCp)₂(bis(i-propylcyclopentadienyl)nickel), bis[1-dimethylamino-2-methyl-2-butoxy]Ni(II) (bis[l-dimethylamino-2-methyl-2-butoxy]Ni(II)), or a derivative thereof, without being limited thereto.

In some embodiments, the metal precursor may include manganese (Mn). In this case, the metal precursor may include Mn(thd)₃ (thd=2,2,6,6-tetramethyl-3,5-heptanedionate), manganese oxalate, MnCp₂, Mn(Me₄Cp)₂, Mn(EtCp)₂), Mn(btsa)₂ (btsa=bis(trimethylsilyl)amide), or a derivative thereof, without being limited thereto.

In some embodiments, the metal precursor may molybdenum (Mo). In this case, the metal precursor may include (CpR)₂Mo(NR′) (each of R and R′ is hydrogen (H) or a C1-C10 alkyl group), bis(t-butyl imido)bis(dimethylamino) molybdenum (VI), molybdenum (VI) dioxide bis(2,2,6,6-tetramethyl-3,5-heptanedionate), or a derivative thereof, without being limited thereto.

In some embodiments, the metal precursor may include tantalum (Ta). In this case, the metal precursor may include pentakisdimethylaminotantalum (TADMA, Ta(NMe₂)₅), pentakisdiethylaminotantalum (PDEAT, Ta(NEt₂)₅), pentakis(methylethylamido)tantalum (PMEAT, Ta(NMeEt)s), tert-butyliminotris(dimethylamino)tantalum (TBTDMT, tBuNTa(NMe₂)₃), tert-butyliminotris(diethylamino)tantalum (TBTDET, tBuNTa(NEt₂)₃), tert-butyliminotris(methylethylamino)tantalum (TBTMET, tBuNTa(NMeEt)₃), ethylimido-tris(dimethylamido)tantalum ((EtN)Ta(NMe₂)₃), ethylimido-tris(diethylamido)tantalum ((EtN)Ta(NEt₂)₃), ethylimido-tris(ethylmethylamido)tantalum ((EtN)Ta[N(Et)Me]₃), tert-amylimido-tris(dimethylamido)tantalum (TAIMATA, (tAmylN)Ta(NMe₂)₃, tert-amylimido-tris(diethylamido)tantalum (TAIEATA, (tAmylN)Ta(NEt₂)₃), tert-amylimido-tris(ethylmethylamido)tantalum (TAIMATA, (tAmylN)Ta([N(Et)Me]₃), or a derivative thereof, without being limited thereto.

In some embodiments, the metal precursor may include niobium (Nb). In this case, the metal precursor may include pentakisdimethylaminoniobium (PDMAN, Nb(N(CH₃)₂)₅), pentakisdiethylaminoniobium (PDEAN, Nb(NEt₂)₅), pentakis(methylethylamido)niobium (PMEAN, Nb(NMeEt)s), tert-butyliminotris(dimethylamino)niobium (TBTDMN, tBuNNb(NMe₂)₃), tert-butyliminotris(diethylamino)niobium (TBTDEN, tBuNNb(NEt₂)₃), tert-butyliminotris(methylethylamino)niobium (TBTMEN, tBuNNb(NMeEt)₃), ethylimido-tris(dimethylamido) niobium ((EtN)Nb(NMe₂)₃), ethylimido-tris(diethylamido)niobium ((EtN)Nb(NEt₂)₃), ethylimido-tris(ethylmethylamido)niobium ((EtN)Nb[N(Et)Me]₃), tert-amylimido-tris(dimethylamido)niobium (NBIMANB, (NbmylN)Nb(NMe₂)₃, tert-amylimido-tris(diethylamido)niobium (NBIEANB, (NbmylN)Nb(NEt₂)₃), tert-amylimido-tris(ethylmethylamido)niobium (NBIMANB, (NbmylN)Nb([N(Et)Me]₃), or a derivative thereof, without being limited thereto.

In some embodiments, the metal precursor may include cesium (Cs). In this case, the metal precursor may include Cs(OtBu), Cs(OiPr), or a derivative thereof, without being limited thereto.

In some embodiments, the metal precursor may include iron (Fe). In this case, the metal precursor may include iron (III) acetylacetonate, without being limited thereto.

The metal precursor is not limited to the examples described above and may be selected from known precursors.

The formation of the metal-containing monolayer 154 may be performed in a vacuum atmosphere. For example, the formation of the metal-containing monolayer 154 may be performed in a plasma atmosphere while maintaining a pressure of about 1 mTorr to about 500 mTorr, for example, about 1 mTorr to about 100 mTorr, and a temperature of about 10° C. to about 300° C., for example, about 30° C. to about 200° C. The metal-containing monolayer 154 may include a single molecular layer selectively bonded to the organic ligand monolayer 152.

When the metal precursor is supplied in vapor form onto the resultant structure of FIG. 2E in which the organic ligand monolayer 152 and the resist lower film 120 are exposed together, a metal ion derived from the metal precursor in a plasma atmosphere may be selectively linked only to a chelating group of an organic ligand that constitutes the organic ligand monolayer 152. Accordingly, the metal-containing monolayer 154 may be selectively formed only on the organic ligand monolayer 152, from among the organic ligand monolayer 152 and the resist lower film 120.

Referring to FIG. 1, in process P30C, in the resultant structure of FIG. 2F, a process of forming the organic ligand monolayer 152 that is selectively bonded to a metal atom exposed on the substrate 102 by supplying a vapor-phase organic ligand precursor onto the substrate 102 and a process of forming the metal-containing monolayer 154 that is selectively bonded to the organic ligand monolayer 152 by supplying a vapor-phase metal precursor onto the substrate 102 may be performed at least once to form a metal-organic framework pattern 150.

Process P30C is described in further detail with reference to FIGS. 2G and 2H. Similar to the process of forming the organic ligand monolayer 152 described with reference to FIG. 2E, a vapor-phase organic ligand precursor may be supplied onto the substrate 102 in the resultant structure of FIG. 2F, and thus, a new organic ligand monolayer 152 that is selectively bonded to a metal atom included in the metal-containing monolayer 154 may be formed.

A vapor-phase organic ligand precursor supplied onto a surface of the metal-containing monolayer 154 may include a bidentate ligand having two reactive groups, and one of two reactive groups included in the organic ligand precursor may be coordinately bonded to a metal atom exposed on the surface of the metal-containing monolayer 154, and thus, the organic ligand monolayer 152 may be selectively formed on the surface of the metal-containing monolayer 154.

Afterwards, the process of forming the metal-containing monolayer 154 described with reference to FIG. 2F and the process of forming the organic ligand monolayer 152 described with reference to FIG. 2G may be alternately and repeatedly performed on the resultant structure of FIG. 2G. Thus, a metal-organic framework pattern 150 having a desired thickness TH2 in the vertical direction (Z direction) may be formed on the photoresist pattern 130P by using a selective bottom-up growth method. The metal-organic framework pattern 150 may have a structure in which a plurality of organic ligand monolayers 152 and a plurality of metal-containing monolayers 154 are alternately stacked one-by-one in the vertical direction (Z direction) that is perpendicular to the main surface 102M of the substrate 102.

In some embodiments, a metal structure network included in the photoresist pattern 130P and the metal-containing monolayer 154 included in the metal-organic framework pattern 150 may include the same metal. For example, each of the metal structure network included in the photoresist pattern 130P and the metal-containing monolayer 154 included in the metal-organic framework pattern 150 may include tin (Sn), without being limited thereto.

In other embodiments, the metal structure network included in the photoresist pattern 130P and the metal-containing monolayer 154 included in the metal-organic framework pattern 150 may include different metals. For example, the metal structure network included in the photoresist pattern 130P may include tin (Sn), and the metal-containing monolayer 154 included in the metal-organic framework pattern 150 may include a metal (e.g., copper (Cu), aluminum (Al), or titanium (Ti)), which has a greater etch resistance than Sn, without being limited thereto.

Referring to FIGS. 1 and 2I, in process P40, the resist lower film 120 may be etched by using the metal-organic framework pattern 150 and the photoresist pattern 130P as an etch mask. Partial regions of the device layer 110, which are exposed as the result of the etching, may be etched, and thus, a plurality of trenches 110T may be formed in the device layer 110.

Referring to FIG. 2J, the metal-organic framework pattern 150, the photoresist pattern 130P, and the resist lower film 120, which remain on the top surface of the device layer 110 in which the plurality of trenches 110T are formed, may be removed.

Referring to FIG. 2K, a plurality of conductive layers 160 may be formed to fill the plurality of trenches 110T formed in the device layer 110.

In embodiments, the plurality of conductive layers 160 may include copper (Cu), molybdenum (Mo), tungsten (W), cobalt (Co), ruthenium (Ru), manganese (Mn), titanium (Ti), tantalum (Ta), aluminum (Al), titanium nitride (TiN), tantalum nitride (TaN), a combination thereof, or an ally thereof, without being limited thereto.

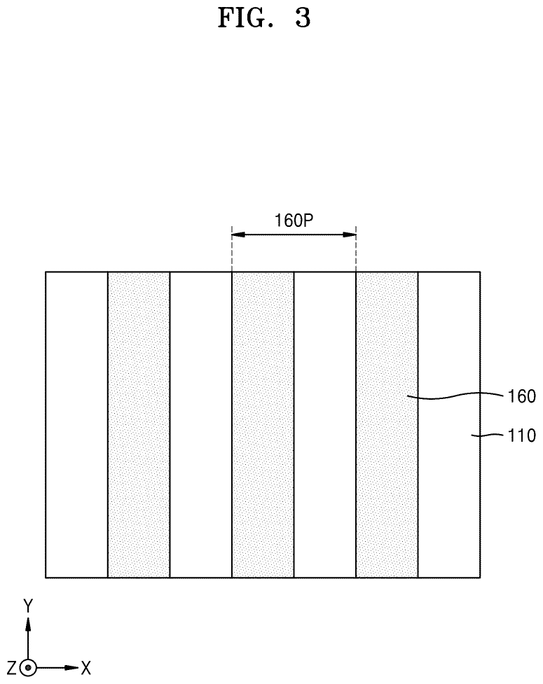

FIG. 3 is a plan view of the plurality of conductive layers 160 and the device layer 110, which are formed with reference to FIG. 2K.

Referring to FIGS. 2K and 3, the plurality of conductive layers 160 may include a plurality of line patterns, which are arranged at a pitch 160P greater than about 5 nm and less than about 28 nm in a first direction (X direction) parallel to a main surface 102M of the substrate 102 and are apart from each other in the first direction (X direction).

In the method of manufacturing the IC device, which has described with reference to FIGS. 1 and 2A to 2K, the photoresist pattern 130P may be formed to a relatively small thickness, and the metal-organic framework pattern having the desired thickness TH2 in the vertical direction (Z direction) may be formed on the photoresist pattern 130P due to a selective bottom-up growth method using metal atoms included in the photoresist pattern 130P as seeds. In the method of manufacturing the IC device according to the present disclosure, the device layer 110 located at a lower position may be etched by using the photoresist pattern 130P as the metal-organic framework pattern 150 as etch masks, and the photoresist pattern 130P may be formed by using an exposure process with a much lower dose than when the device layer 110 is etched by using the photoresist pattern 130P alone. In addition, even when patterns having a relatively small pitch are formed in the device layer 110, a sufficient thickness for an etch mask may be achieved by using the metal-organic framework pattern 150 without the need to increase an aspect ratio of the photoresist pattern 130P. Accordingly, in the method of manufacturing the IC device according to the present disclosure, there may be no need to increase the thickness of the photoresist pattern 130P to ensure etch resistance properties of the etch mask. Thus, when the photoresist pattern 130P is formed, a desired sensitivity and a desired resolution may be achieved even by applying a relatively low dose, and line edge roughness (LER) of the photoresist pattern 130P may improve. Furthermore, productivity in the process of manufacturing the IC device may be improved by significantly reducing an exposure time and a dose for forming the photoresist pattern 130P. Therefore, in the method of manufacturing the IC device, according to the present disclosure, even when a device region (e.g., the semiconductor die area DA) has a reduced area and a pitch of components included in the device is reduced due to downscaling, productivity in the process of manufacturing the IC device may improve, and the reliability of the IC device obtained by the method according to the inventive concept may increase.

While the inventive concept has been particularly shown and described with reference to embodiments thereof, it will be understood that various changes in form and details may be made therein without departing from the spirit and scope of the following claims.

What is claimed is:

1. A method of manufacturing an integrated circuit device, the method comprising:
forming a device layer on a substrate;
forming a photoresist pattern on a partial region of the device layer by using a photolithography process, the photoresist pattern comprising a metal structure network;
forming a metal-organic framework pattern on the photoresist pattern, the metal-organic framework pattern comprising at least one organic ligand layer and at least one metal-containing layer; and
etching the device layer by using the metal-organic framework pattern and the photoresist pattern as etch masks,
wherein the forming of the metal-organic framework pattern comprises:
forming an organic ligand monolayer by supplying a vapor-phase organic ligand precursor onto the substrate, the organic ligand monolayer being selectively bonded to metal atoms exposed on the substrate; and
forming a metal-containing monolayer by supplying a vapor-phase metal precursor onto a resultant structure from the forming of the organic ligand monolayer, the metal-containing monolayer being selectively bonded to the organic ligand monolayer.

2. The method of claim 1, wherein the forming of the metal-organic framework pattern further comprises alternately repeating the forming of the organic ligand monolayer and the forming of the metal-containing monolayer at least once.

3. The method of claim 1, wherein the forming of the photoresist pattern comprises forming the photoresist pattern such that the photoresist pattern has a thickness greater than 10 Å and less than 100 Å in a vertical direction that is perpendicular to a main surface of the substrate.

4. The method of claim 1, wherein the forming of the metal-organic framework pattern comprises forming the metal-organic framework pattern such that the metal-organic framework pattern has a thickness greater than a thickness of the photoresist pattern in a vertical direction that is perpendicular to a main surface of the substrate.

5. The method of claim 1, further comprising, after the forming of the device layer and before the forming of the photoresist pattern, forming a resist lower film comprising a carbon-containing film, on the device layer,
wherein the photoresist pattern is formed on the resist lower film.

6. The method of claim 1, wherein, in the forming of the organic ligand monolayer, the organic ligand precursor comprises a bidentate ligand having a structure as in Formula 1:
X¹-A-X², [Formula 1]
wherein A denotes a substituted or unsubstituted C6-C60 arylene group or a substituted or unsubstituted C6-C60 heteroarylene group, and
each of X¹ and X² denotes a carboxylic group, an aldehyde group, an amino group, a pyridyl group, a tetrazolyl group, a 2-(diphenylphosphino) ethyl group, a phosphoryl group, or a sulfonyl group.

7. The method of claim 1, wherein, in the forming of the metal-containing monolayer, the metal precursor has a structure as in Formula 2:
M(R¹)m(R²)n, [Formula 2]
wherein M denotes a metal element,
R¹ denotes a C1-C30 linear alkyl group, a C1-C30 branched alkyl group, a C2-C30 alkenyl group, C2-C30 alkynyl group, a C3-C30 cycloalkyl group, a C1-C30 alkoxy group, a C6-C30 aryl group, a C2-C30 heteroaryl group, a C7-C30 alkylaryl group, a C1-C30 alkylamino group, a C1-C30 bis(trialkylsilyl)amino group, a disubstituted phosphoric acid group, a R⁴COO— group, a R⁴SO₃— group, or a R⁴SO₂— group, wherein R⁴ denotes a substituted or unsubstituted C1-C10 alkyl group or a substituted or unsubstituted phenyl group,
R² denotes C1-C10 alkylamine or pyridine,
m is an integer of 2 to 8, and
n is an integer of 0 to 6.

8. The method of claim 1, wherein, in the forming of the metal-containing monolayer, the metal precursor comprises at least one metal element selected from tin (Sn), copper (Cu), aluminum (Al), titanium (Ti), tungsten (W), hafnium (Hf), antimony (Sb), indium (In), bismuth (Bi), silver (Ag), tellurium (Te), gold (Au), lead (Pb), zinc (Zn), zirconium (Zr), vanadium (V), chromium (Cr), cobalt (Co), nickel (Ni), gallium (Ga), manganese (Mn), strontium (Sr), cadmium (Cd), molybdenum (Mo), tantalum (Ta), niobium (Nb), cesium (Cs), barium (Ba), lanthanum (La), cerium (Ce), and iron (Fe).

9. The method of claim 1, wherein the metal structure network of the photoresist pattern comprises a first metal and the metal-organic framework pattern also comprises the first metal.

10. The method of claim 1, wherein the metal structure network of the photoresist pattern comprises a first metal, and the metal-organic framework pattern comprises a second metal that is different from the first metal.

11. The method of claim 1, wherein the forming of the photoresist pattern comprises:
forming, on the device layer, a photoresist film comprising a metal oxide by using a dry deposition process;
exposing a partial region of the photoresist film; and
dry-developing the exposed photoresist film.

12. A method of manufacturing an integrated circuit device, the method comprising:
forming a device layer on a substrate;
forming a resist lower film on the device layer;
forming a photoresist pattern on a partial region of the resist lower film by using a photolithography process such that the photoresist pattern has a first thickness in a vertical direction, the photoresist pattern comprising a metal structure network, wherein the vertical direction is perpendicular to a main surface of the substrate;
forming a metal-organic framework pattern on the photoresist pattern such that the metal-organic framework pattern has a second thickness greater than the first thickness in the vertical direction, the metal-organic framework pattern comprising at least one organic ligand layer and at least one metal-containing layer; and
etching the device layer by using the metal-organic framework pattern and the photoresist pattern as an etch mask,
wherein the forming of the metal-organic framework pattern comprises:
forming an organic ligand monolayer by supplying a vapor-phase organic ligand precursor onto the substrate, the organic ligand monolayer being selectively bonded to metal atoms exposed on the substrate; and
forming a metal-containing monolayer by supplying a vapor-phase metal precursor onto a resultant structure from the forming of the organic ligand monolayer, the metal-containing monolayer being selectively bonded to the organic ligand monolayer,
wherein, in the forming of the organic ligand monolayer, the organic ligand precursor comprises a bidentate ligand, and,
in the forming of the metal-containing monolayer, the metal precursor comprises at least one metal element selected from tin (Sn), copper (Cu), aluminum (Al), titanium (Ti), tungsten (W), hafnium (Hf), antimony (Sb), indium (In), bismuth (Bi), silver (Ag), tellurium (Te), gold (Au), lead (Pb), zinc (Zn), zirconium (Zr), vanadium (V), chromium (Cr), cobalt (Co), nickel (Ni), gallium (Ga), manganese (Mn), strontium (Sr), cadmium (Cd), molybdenum (Mo), tantalum (Ta), niobium (Nb), cesium (Cs), barium (Ba), lanthanum (La), cerium (Ce), and iron (Fe).

13. The method of claim 12, wherein the forming of the metal-organic framework pattern further comprises alternately repeating the forming of the organic ligand monolayer and the forming of the metal-containing monolayer at least once.

14. The method of claim 12, wherein, in the forming of the organic ligand monolayer, the organic ligand precursor comprises a bidentate ligand having a structure as in Formula 1:
X¹-A-X², [Formula 1]
wherein A denotes a substituted or unsubstituted C6-C60 arylene group or a substituted or unsubstituted C6-C60 heteroarylene group, and
each of X¹ and X² denotes a carboxylic group, an aldehyde group, an amino group, a pyridyl group, a tetrazolyl group, a 2-(diphenylphosphino) ethyl group, a phosphoryl group, or a sulfonyl group.

15. The method of claim 12, wherein the etching of the device layer comprises forming a plurality of trenches in the device layer, and
wherein the method further comprises, after the etching of the device layer, forming a plurality of conductive layers filling the plurality of trenches.

16. The method of claim 12, wherein the photoresist pattern comprises a plurality of line patterns arranged at a pitch greater than 5 nm and less than 28 nm in a first direction parallel to the main surface of the substrate, the plurality of line patterns being apart from each other in the first direction.

17. The method of claim 12, wherein the metal structure network comprises a metal oxide.

18. A method of manufacturing an integrated circuit device, the method comprising:
forming an insulating film on a substrate;
forming a resist lower film on the insulating film;
forming a photoresist pattern on a partial region of the resist lower film by using a photolithography process such that the photoresist pattern has a first thickness in a vertical direction, the photoresist pattern comprising a metal structure network, wherein the vertical direction is perpendicular to a main surface of the substrate;
forming a metal-organic framework pattern on the photoresist pattern such that the metal-organic framework pattern has a second thickness greater than the first thickness in the vertical direction, the metal-organic framework pattern comprising at least one organic ligand layer and at least one metal-containing layer;
forming a plurality of trenches in the insulating layer by etching partial regions of the insulating layer by using the metal-organic framework pattern and the photoresist pattern as an etch mask; and
forming a plurality of conductive layers filling the plurality of trenches,
wherein the forming of the metal-organic framework pattern further comprises:
forming an organic ligand monolayer by supplying a vapor-phase organic ligand precursor onto the substrate, the organic ligand monolayer being selectively bonded to metal atoms exposed on the substrate;
forming a metal-containing monolayer by supplying a vapor-phase metal precursor onto a resultant structure from the forming of the organic ligand monolayer, the metal-containing monolayer being selectively bonded to the organic ligand monolayer; and
alternately repeating the forming of the organic ligand monolayer and the forming of the metal-containing monolayer such that the metal-organic framework pattern having the second thickness is obtained.

19. The method of claim 18, wherein, in the forming of the organic ligand monolayer, the organic ligand precursor comprises a bidentate ligand having a structure as in Formula 1:
X¹-A-X², [Formula 1]
wherein A denotes a substituted or unsubstituted C6-C60 arylene group or a substituted or unsubstituted C6-C60 heteroarylene group, and
each of X¹ and X² denotes a carboxylic group, an aldehyde group, an amino group, a pyridyl group, a tetrazolyl group, a 2-(diphenylphosphino) ethyl group, a phosphoryl group, or a sulfonyl group.

20. The method of claim 18, wherein, in the forming of the metal-containing monolayer, the metal precursor has a structure as in Formula 2:
M(R¹)ₘ(R²)ₙ, [Formula 2]
wherein M denotes a metal element,
R¹ denotes a C1-C30 linear alkyl group, a C1-C30 branched alkyl group, a C2-C30 alkenyl group, a C2-C30 alkynyl group, a C3-C30 cycloalkyl group, a C1-C30 alkoxy group, a C6-C30 aryl group, a C2-C30 heteroaryl group, a C7-C30 alkylaryl group, a C1-C30 alkylamino group, a C1-C30 bis(trialkylsilyl)amino group, a disubstituted phosphoric acid group, a R⁴COO— group, a R⁴SO₃— group, or a R⁴SO₂— group, wherein R⁴ denotes a substituted or unsubstituted C1-C10 alkyl group or a substituted or unsubstituted phenyl group,
R² is C1-C10 alkylamine or pyridine,
m is an integer of 2 to 8, and
n is an integer of 0 to 6.
